(19) United States
(12) Patent Application Publication
(10) Pub. No.: US 2005/0200369 A1
(43) Pub. Date: Sep. 15, 2005

(54) Resistance metering device having probes on bar clamps

(76) Inventor: Andre Langevin, Laprairie (CA)

Correspondence Address: INVENTARIUM, SUITE 1607, 4050 ROSEMONT BLVD., MONTREAL, QC, H1X1M4, CA

(21) Appl. No.: 10/798,771

(22) Filed: Mar. 12, 2004

(51) Int. Cl. G01R 27/08

(52) U.S. Cl. 324/691

(57) ABSTRACT

A resistance metering device uses versatile pads which can be used, depending on where they are connected, as either probes or DC connectors. When not connected, the same probes can be used as the complementary pad to a pair of pads wherein only one need be connected to either serve as a probe or DC connector while the other presses on the opposite surface in order to procure a tight contact surface where leakage is unlikely to occur. Each pair of probes, whether connected or not, is releasably attached to a clamp which provides the tightening means.

### BACKGROUND OF THE INVENTION

1. Field of the Invention

The invention relates generally to measuring devices but more particularly to an ohmmeter adapted for work on high powered lines and related high voltage, high amperage devices.

2. Background of the Invention

Multimeters are used for measuring voltage and current on small appliances and household power lines. When it comes to high voltages such as for industrial use or at power substations or even at the source where voltages over 100,000 volts are common and where can be found circuit breakers 50 feet long, a basic multimeter is less than adequate.

To overcome this limitation, a number of inventors have tried to modify or adapt tools to answer this need. When it comes to measuring resistance, there is no need to power up the line at great voltage. Rather, the part of the circuit or the circuit component to be measured has its power cut off so that the measuring instrument itself will select a direct current (DC) of a certain value which will be pushed through the selected circuit part and/or component in order to measure the resistance by way of a voltmeter and using R=V/I. This technique allows for the measurement of very small resistance across very large components.

What is still inadequate in the prior art and in need of improvement is a way for securing both the measuring probes and the current probes to the circuit or component to be measured. The prior art consists primarily in the use of articulated jaw type clamps that clip onto circuit wiring or components. While this is fine some of the time, it can result in a weak contact which can result in leakage and point contact losses which can provide faulty measurements. Also it is very useful to have a device with jaws built in a manner to penetrate oxidation that could occur on the device under test.

There is therefore a need for improved clamping means to eliminate losses and leakage and improve measurements capabilities.

### SUMMARY OF THE INVENTION

It is a first object of this invention to provide for a means to procure a tight connection of the DC probes to the surface to be measured.

It is a second object of this invention to provide for a means to procure a tight connection of the voltmeter measuring probes to the surface to be measured.

It is a third object of this invention to provide for a means to procure an easily dismountable set of probes for handheld operation.

It is a fourth object of this invention to provide for a means to procure probes and clamps of variable shapes so that they conform to a variety of shaped structures to be measured.

It is a fifth object of this invention to penetrate the oxidation that naturally occurs on most of the devices under test by being allowing the clamps to apply enough pressure on the surface to be measured.

In order to do so, this instant invention uses versatile pads which can be used, depending on where they are connected, as either probes or DC connectors. When not connected, the same probes can be used as the complementary pad to a pair of pads wherein only one need be connected to either serve as a probe or DC connector while the other presses on the opposite surface in order to procure a tight contact surface where leakage is unlikely to occur. Each pair of probes, whether connected or not, is releasably attached to a clamp which provides the tightening means.

The foregoing and other objects, features, and advantages of this invention will become more readily apparent from the following detailed description of a preferred embodiment with reference to the accompanying drawings, wherein the preferred embodiment of the invention is shown and described, by way of examples. As will be realized, the invention is capable of other and different embodiments, and its several details are capable of modifications in various obvious respects, all without departing from the invention. Accordingly, the drawings and description are to be regarded as illustrative in nature, and not as restrictive.

### BRIEF DESCRIPTION OF THE PREFERRED EMBODIMENT

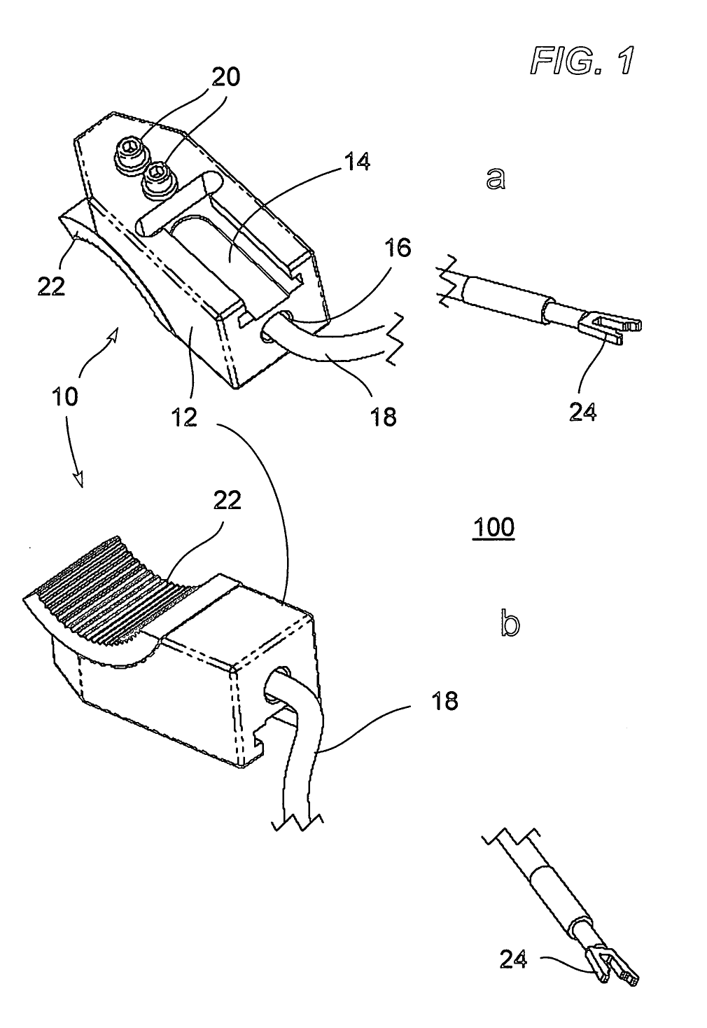

FIGS. 1ab Perspective views favoring the back and the front of the probes.

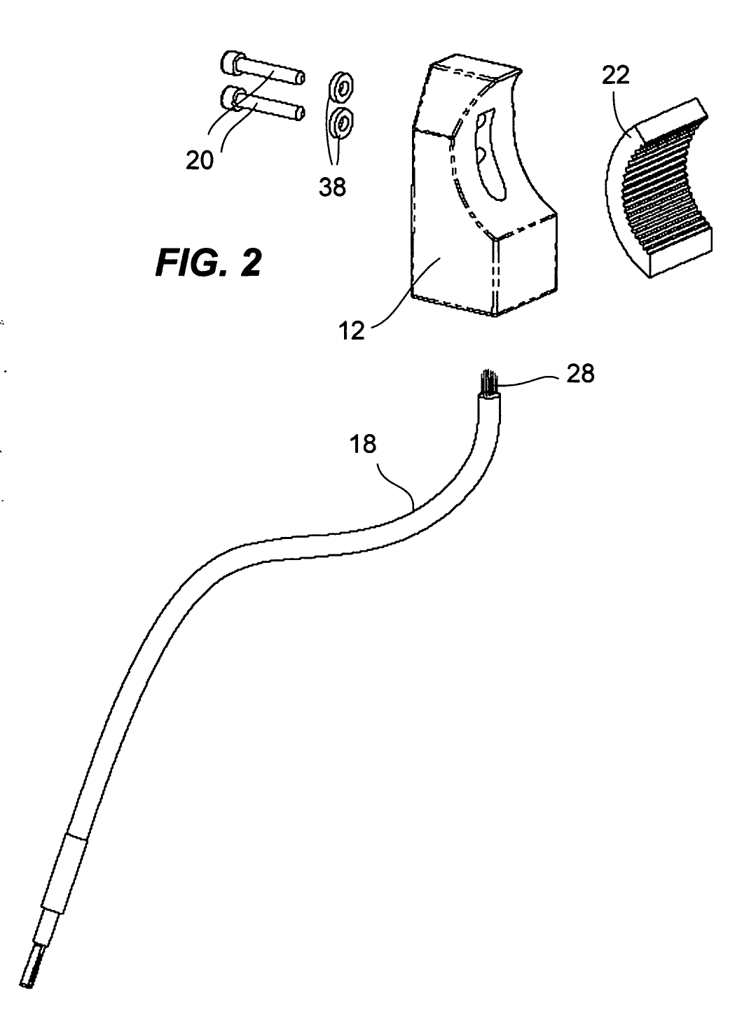

FIG. 2 Exploded perspective view of a probe.

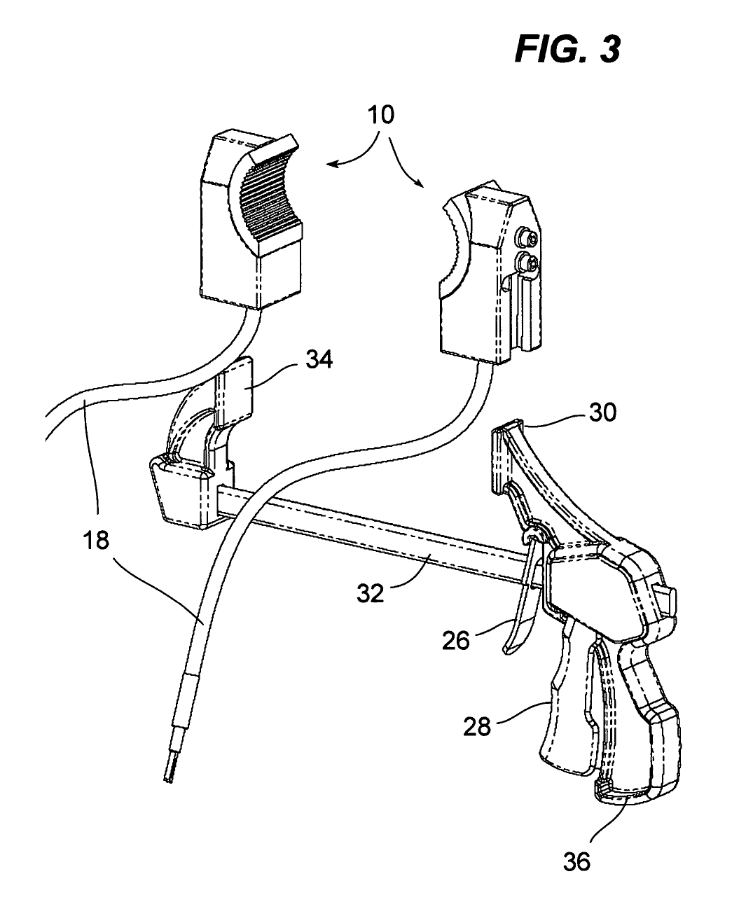

FIG. 3 Exploded perspective view of the probes and the bar clamp.

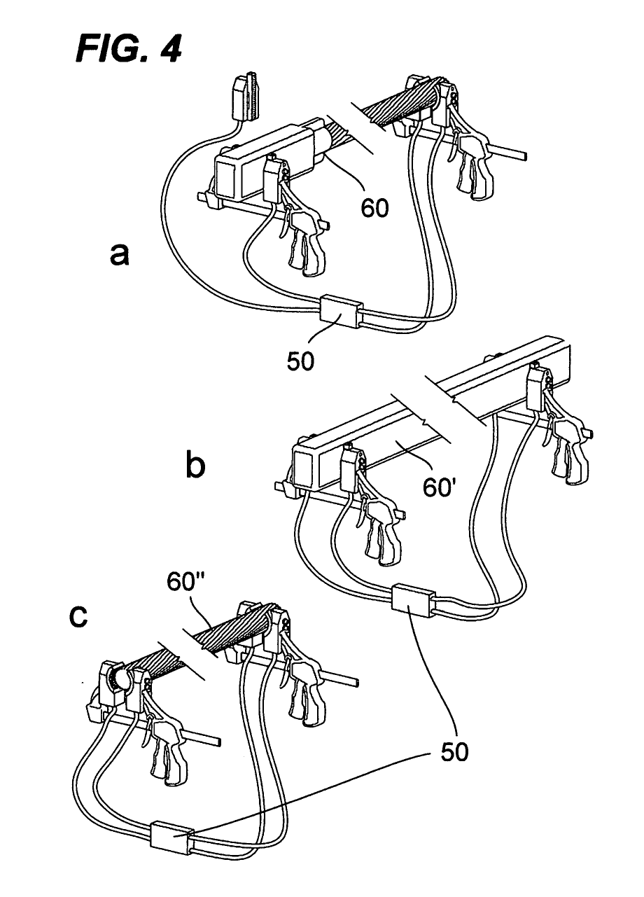

FIGS. 4abc Perspective views of the metering device in use with diferent types of probe combinations and different types of components.

### DETAILED DESCRIPTION OF THE PREFERRED EMBODIMENT

A resistance metering device (100) consists of probes (10) made up of a body (12) having four faces on its long side. An attachment groove (14) situated on one of the four faces for attachment to a clamp jaw (30); a lead passageway (16) for passing a lead (18) therethrough, situated at the center of the body and running parallel to the long side of the body (12). The word probe (10) is used hereinafter to describe the part regardless as to whether it is used as a measuring probe, connected to a power supply to push current or simply as a tightening means.

At least one mechanical fastener (20), preferably but not necessarily with a washer, (36) serves the double duty of fastening the lead (18) so that it makes a strong contact with a metal contact (22) and at the same time fastening that metal contact (22) to the body (12) on a face opposite that of the attachment groove (14). The metal contact (22) can come in various shapes, not limited to the crescent shape or flat shape illustrated here without departing from the scope of this invention. The appropriate shape is selected so as to best accommodate the various shapes of the components they will have to interact with. For example, FIGS. 4abc show various combinations of metal contact shapes to fit the device to be measured (60, 60′, 60″) and with readout obtained on a standard power supply/tester (50).

Referring to FIG. 3, sliding the attachment groove (14) over the clamp jaw (30) of a standard bar clamp (40), as commonly used by carpenters, is all that is needed to be ready for measurement. An appropriate location with an appropriately shaped metal contact (22) is chosen, the bar clamp (40) is released by depressing its lock (26), a bar (32) is slid so that a secondary jaw (34) closes in on the primary jaw (30), and then a lock (26) is released and a trigger (28) is actuated until enough pressure is applied to securely install the probe (12). The action is repeated so that the “+” and “−” sides of the voltmeter, represented in FIGS. 4abc as a combo power supply/tester (50) are connected and at least one side of the power supply/tester (50) is connected. The other probe (10) can be likewise installed, or it can be handheld and moved to different areas, free to measure along a component (FIG. 4a).

1. A resistance metering device having probes on a bar clamp with two leads providing direct current and two leads serving to measure a voltage with a voltmeter from which a resistance is deducted and comprising:
a plurality of probes each having a body comprised of four faces on their long side;
an attachment groove situated on one of the four faces for attachment to a clamp jaw;
a lead passageway for passing a lead therethrough;
at least one mechanical fastener passing through said face so as to fixedly attach a metal contact situated on an opposite face as well as fixedly attaching said lead;
a bar clamp having jaws and over which jaws are slid said attachment grooves from said probes.

2. A resistance metering device as in claim 1 wherein:
said probes having metal contacts that are crescent shaped

3. A resistance metering device as in claim 1 wherein:
said probes having metal contacts that are bar shaped.

4. A method for measuring the resistance of components wherein an appropriate location with an appropriately shaped metal contact is chosen and following steps are executed consisiting of;
a first procedure:
a bar clamp is released by depressing its lock;
a bar part of a bar clamp is slid so that a secondary jaw closes in on a primary jaw and then a lock is released and a trigger is actuated until enough pressure is applied to securely install a probe;
said first procedure repeated for each additional said probe;
power supply connected probes are connected and at least one measuring probe is installed following said first procedure;
a second measuring probe is installed following said first procedure;
a measurement of voltage is made and a resistance is deduced.

5. A method for measuring the resistance of components as in claim 4 wherein:
only one measuring probe is installed with a second measuring probe free to measure along a component.
